(19) United States
(12) Patent Application Publication
(10) Pub. No.: US 2012/0211054 A1
(43) Pub. Date: Aug. 23, 2012

(54) SOLAR CELL MODULE

(76) Inventor: Yoshinori Suga, Mishima-shi (JP)

(21) Appl. No.: 13/505,302

(22) PCT Filed: Nov. 6, 2009
(86) PCT No.: PCT/JP2009/068981

§ 371 Date: May 1, 2012

(51) Int. Cl. H01L 31/052

(52) U.S. Cl. 136/246

(57) ABSTRACT

Disclosed is a solar cell module capable of suppressing light leakage from a front plate and improving an optical confinement property. A solar cell module 1 includes a plurality of bifacial solar cell elements 2, a front plate 4 which is arranged on the front side of the solar cell elements 2, and a back plate 5 which is arranged on the back side of the solar cell elements 2 and has a light-reflecting surface 5a reflecting sunlight incident into the module from the module front side. When the refractive index of the front plate 4 is n, the inclination angle Φ (radian unit) of the light-reflecting surface 5a relative to the array direction of the solar cell elements 2 is set as follows between a cell interval center line A and a cell end line C. That is, in a region X between the cell interval center line A and a near-cell line D, the relationship (Φ>0.5×sin ⁻¹ (1/n) is established. In a region Y near the cell end line C, the relationship (Φ<0.5×sin ⁻¹ (1/n) is established.

### TECHNICAL FIELD

The present invention relates to a solar cell module having solar cell elements.

### BACKGROUND ART

In the related art, for example, as described in Patent Literature 1, a solar cell module is known in which a plurality of solar cell elements are arranged between a cover glass (front plate) and a V sheet having a plurality of V groove-like light-reflecting surfaces.

### Citation List

### Patent Literature

[Patent Literature 1] Japanese Unexamined Patent Application Publication No. 2002-26364

### SUMMARY OF INVENTION

### Technical Problem

However, in the related art, when sunlight incident into a portion separated from the solar cell element is reflected by the light-reflecting surface, reflected light leaks outside the solar cell module without being totally reflected by the surface of the front plate. In this case, the confinement property of light in the solar cell module is deteriorated, resulting in degradation in power generation efficiency.

An object of the invention is to provide a solar cell module capable of suppressing light leakage from a front plate and improving an optical confinement property.

### Solution to Problem

The inventors have made an in-depth study on the performance or the like of the solar cell module, have found that, if the inclination angle of the light-reflecting surface of the back plate is in an appropriate range, incident sunlight is appropriately confined in the solar cell module, thereby efficiently condensing sunlight on the solar cell element, and have completed the invention.

That is, the invention provides a solar cell module. The solar cell module includes a plurality of solar cell elements, a front plate which is arranged on the front side of the solar cell elements, and a back plate which is arranged on the back side of the solar cell elements and has a light-reflecting surface reflecting sunlight incident from the front plate toward the front plate. The light-reflecting surface is inclined relative to the array direction of the solar cell elements to be concave, and when the refractive index of the front plate is n, the inclination angle Φ of the light-reflecting surface in a concave extreme point-side portion of the light-reflecting surface is greater than 0.5×sin ⁻¹(1/n) rad.

In this solar cell module, sunlight incident from the front plate is reflected by the light-reflecting surface of the back plate, and reflected light is reflected by the surface (the interface between the front plate and an air layer) of the front plate and condensed on the front surface of the solar cell element. At this time, if the inclination angle Φ of the light-reflecting surface in the concave extreme point-side portion of the light-reflecting surface is greater than 0.5×sin ⁻¹(1/n) rad, even when sunlight is incident into the portion separated from the solar cell element, a total reflection condition on the surface of the front plate is satisfied, and leak of sunlight from the front plate outside the solar cell module is suppressed. Therefore, it is possible to improve the confinement property of sunlight in the solar cell module.

It is preferable that, at a position corresponding to near the edge of each solar cell element, there is a point where the inclination angle Φ of the light-reflecting surface becomes 0.5×sin ⁻¹(1/n) rad.

It is preferable that the light-reflecting surface is inclined relative to the array direction of the solar cell elements to be concave in an interval region between the solar cell elements, and the inclination angle Φ of the light-reflecting surface on the solar cell element side in the interval region between the solar cell elements is smaller than 0.5×sin ⁻¹(1/n) rad.

In this case, the inclination angle Φ of the light-reflecting surface on the solar cell element side in the interval region between the solar cell elements is smaller than the inclination angle Φ of the light-reflecting surface in the concave extreme point-side portion of the light-reflecting surface, making it easy to confine sunlight incident from all directions confined in the solar cell module. Therefore, it is possible to further improve the confinement property of sunlight in the solar cell module.

It is preferable that, when the array pitch of the solar cell elements is P, a condensing magnification relative to the array direction of the solar cell elements is a, and the distance between the solar cell element to the surface of the front plate is t, the inclination angle Φ of the light-reflecting surface in a concave extreme point-side portion of the light-reflecting surface is expressed by the following expression.

$$\begin{matrix} [ Equation 1 ] & \\ 0.5 \times {sin}^{- 1} ( \frac{1}{n} ) rad < Φ < \frac{1}{2} \cdot \frac{- 8 t a + \sqrt{64 {t}^{2} {a}^{2} + 4 {P}^{2} a + 2 {P}^{2} {a}^{2} - 6 {P}^{2}}}{P ( a - 1 )} rad & \end{matrix}$$

In this case, since sunlight totally reflected by the surface of the front plate is incident on the front surface of the solar cell element evenly, it is possible to prevent the occurrence of a local heat generation phenomenon (hot spot phenomenon) of the solar cell element. It is also possible to prevent the back plate from increasing in thickness, thereby preventing an increase in the thickness of the solar cell module.

### Advantageous Effects of Invention

According to the invention, it is possible to suppress light leakage from the front plate and to improve an optical confinement property. Therefore, even when the solar cell element decreases in width, it becomes possible to efficiently condense sunlight on the solar cell element and to improve power generation efficiency. When the solar cell module is installed on the roof of a house or the roof of an automobile, glitter occurs with difficulty, thereby improving appearance.

### BRIEF DESCRIPTION OF DRAWINGS

FIG. 1 is a sectional view showing an embodiment of a solar cell module according to the invention.

FIG. 2 is a sectional view showing a modification of the solar cell module shown in FIG. 1.

FIG. 3 is a conceptual diagram for deriving an appropriate inclination angle range of a light-reflecting surface shown in FIG. 1.

FIG. 4 is a conceptual diagram for deriving an appropriate inclination angle range of a light-reflecting surface shown in FIG. 1.

FIG. 5 is a conceptual diagram for deriving an appropriate inclination angle range of a light-reflecting surface shown in FIG. 1.

FIG. 6 is a graph showing a power generation performance ratio with changes in an inclination angle of a light-reflecting surface in various ways when there is a change point in an inclination angle of a light-reflecting surface and when there is no change point.

FIG. 7 is a table showing appearance quality of a solar cell module when an inclination angle of a light-reflecting surface has changed in various ways.

### REFERENCE SIGNS LIST

1: solar cell module, 2: solar cell element, 3: seal resin portion, 4: front plate, 5: back plate, 5a: light-reflecting surface.

### Description of Embodiments

Hereinafter, a preferred embodiment of a solar cell module according to the invention will be described in detail with reference to the drawings.

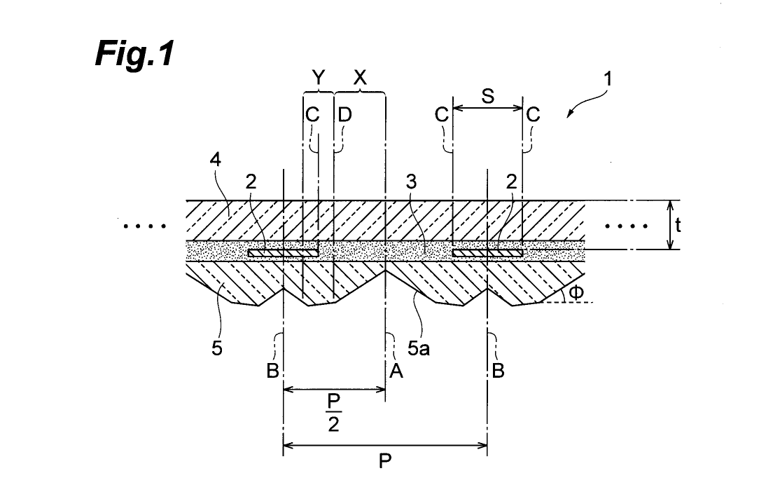

FIG. 1 is a sectional view showing an embodiment of a solar cell module according to the invention. Referring to FIG. 1, a solar cell module 1 of this embodiment includes a plurality of solar cell elements 2, a seal resin portion 3 which is made of seal resin for fixing the solar cell elements 2, a front plate 4 which is arranged on the front side of the seal resin portion 3, and a back plate 5 which is arranged on the back side of the seal resin portion 3 and has a light-reflecting surface 5a reflecting sunlight incident into the module from the module front side.

The solar cell elements 2 have, for example, an n/p/p+ junction structure in which an n layer and a p layer are formed on a p-type silicon wafer through phosphorus diffusion and boron diffusion. It is preferable that the solar cell elements 2 are of a bifacial type which is configured to generate power on both surfaces. At this time, it is preferable that bifaciality (a power generation performance ratio of both surfaces) of the solar cell elements 2 is equal to or greater than 0.5. The solar cell elements 2 are substantially arranged at a regular-interval pitch P.

As the seal resin forming the seal resin portion 3, for example, ethylene-vinyl acetate copolymer resin (EVA resin), polyvinyl butyral resin, polyethylene resin, or the like is used. The front plate 4 is formed of, for example, a white sheet tempered glass substrate.

The back plate 5 is formed of, for example, a heat-resistant glass substrate or a transparent substrate of transparent resin or the like.

The light-reflecting surface 5a of the back plate 5 is formed in a planar concave-convex shape. Specifically, the light-reflecting surface 5a is formed to be concave relative to the module back side on a line (cell interval center line) A passing through the center of the interval region between the solar cell elements 2 and a line (cell center line) B passing through the center of each solar cell element 2. That is, the light-reflecting surface 5a is formed to become a valley groove portion (concave extreme point) on the cell interval center line A and the cell center line B. It is preferable that the thickness of the back plate 5 on the cell interval center line A is smaller than the thickness of the back plate 5 on the cell center line B.

When the refractive index of the front plate 4 is n, the inclination angle Φ (radian unit) of the light-reflecting surface 5a relative to the array direction of the solar cell elements 2 is set as follows between the cell interval center line A and a line (cell end line) C passing through the end of each solar cell element 2.

That is, in a region X between the cell interval center line A and a line (near-cell line) D near the solar cell element 2, the following relationship is established.

Φ>0.5×sin ⁻¹(1/n)

The near-cell line D is a line which passes through a position at a length corresponding to 20% of the width S of the solar cell element 2 from the cell end line C toward the cell interval center line A.

In a region Y near the cell end line C, the following relationship is established.

Φ<0.5×sin⁻¹(1/n)

The region Y is a region which occupies a length corresponding to ±20% of the width S of the solar cell element 2 relative to the cell end line C.

At this time, when a condensing magnification relative to the array direction of the solar cell elements 2 is a, and the distance (gap) from the solar cell element 2 to the surface of the front plate 4 is t, it is preferable that the inclination angle Φ (radian unit) of the light-reflecting surface 5a in the region X between the cell interval center line A and the near-cell line D satisfies the following relationship.

$$\begin{matrix} [ Equation 2 ] & \\ 0.5 \times {sin}^{- 1} ( \frac{1}{n} ) < Φ < \frac{1}{2} \cdot \frac{- 8 t a + \sqrt{64 {t}^{2} {a}^{2} + 4 {P}^{2} a + 2 {P}^{2} {a}^{2} - 6 {P}^{2}}}{P ( a - 1 )} & \end{matrix}$$

It is particularly preferable that, in the region X between the cell interval center line A and the near-cell line D, the inclination angle Φ of the light-reflecting surface 5a satisfies the following relationship.

0.5×sin⁻¹(1/n)rad<Φ<θ+8°

The angle θ is the solution of the following expression.

$$\begin{matrix}[ Equation 3 ] & \\ \frac{P}{4} + \frac{3 P}{4 a} - tan 2 θ \{ 2 t + \frac{1}{4} tan θ ( P - \frac{P}{a} ) \} = 0 & \end{matrix}$$

In the solar cell module 1 of this embodiment, if sunlight is incident into the module from the module front side, sunlight passes through the front plate 4 and the seal resin portion 3, and is reflected by the light-reflecting surface 5a of the back plate 5. Reflected light is directly incident on the back surface of the solar cell element 2, is totally reflected by the surface of the front plate 4 (a contact interface of the front plate 4 and the air), and is then incident on the front surface of the solar cell element 2.

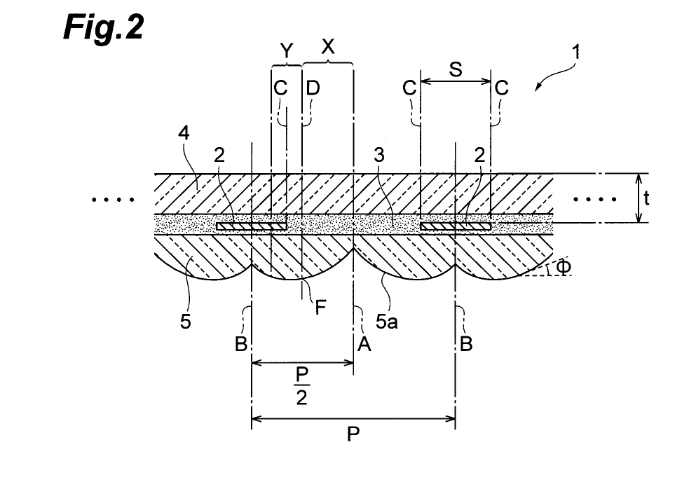

FIG. 2 is a sectional view showing a modification of the solar cell module 1 shown in FIG. 1. The solar cell module 1 shown in FIG. 2 is the same as the above-described solar cell module 1 except for the shape of the back plate 5.

Specifically, the light-reflecting surface 5a of the back plate 5 is formed in a curved concave-convex shape. At this time, the light-reflecting surface 5a is formed to be concave relative to the module back side on the cell interval center line A and the cell center line B. In each of the region X between the cell interval center line A and the near-cell line D and the region Y near the cell end line C, the inclination angle Φ of the light-reflecting surface 5a is the same as described above. The inclination angle Φ at this time is the angle on the tangent to the light-reflecting surface 5a. It is preferable that there is an inflection point F of the curved light-reflecting surface 5a near a position of the light-reflecting surface 5a corresponding to the region Y.

In regard to the curved light-reflecting surface 5a, with the measurement of an average inclination angle from the cell interval center line A to the inflection point F, the inclination angle Φ in the region X is defined.

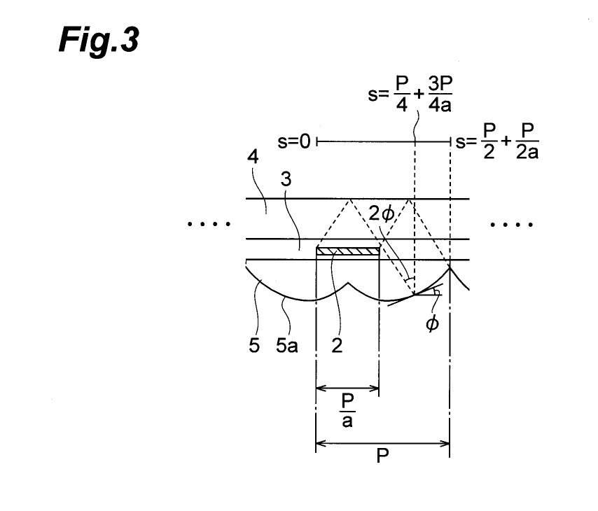

Next, a reason for which the inclination angle Φ of the light-reflecting surface 5a is given by the above-described expression will be described. As in this embodiment, in a condensing solar cell module, as shown in FIG. 3, a solar beam (see a broken line) which is brought back to the solar cell elements 2 by the Snell's total reflection condition based on a difference in the refractive index between the front plate 4 and the air layer is positively utilized. For this reason, in order to maintain condensing performance, it is important to increase the inclination angle Φ of the light-reflecting surface 5a and to convert the direction of the solar beam such that the total reflection phenomenon easily occurs. Accordingly, in the concave extreme point-side portion of the light-reflecting surface 5a in the interval region between the solar cell elements 2, the inclination angle Φ of the light-reflecting surface 5a is greater than 0.5×sin ⁻¹(1/n) rad.

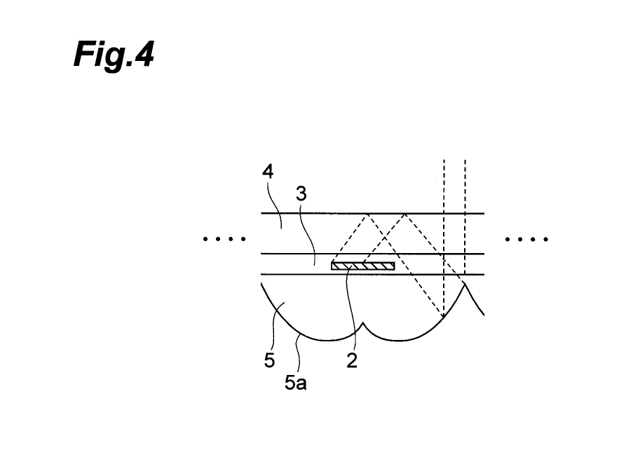

However, in order to minimize the use of the solar cell elements 2 while maintaining reliability of the solar cell module, the light-reflecting surface 5a having an excessively steep inclination angle Φ has a problem pertaining to the practical use. Specifically, if the inclination angle Φ of the light-reflecting surface 5a is excessively steep, as shown in FIG. 4, there is a phenomenon that sunlight which is condensed by the total reflection phenomenon of the front plate 4 excessively converges to a narrow focus on the front side (the side toward the light incident surface of the solar cell module) of the solar cell element 2. This phenomenon causes a hot spot phenomenon that great energy locally excessively increases on the front side of the solar cell element 2 on which light incident energy is originally great. For this reason, there is a problem pertaining to deterioration in seal resin due to the hot spot phenomenon or degradation in reliability due to defective bonding of the solar cell elements 2. In the light-reflecting surface 5a having an excessively steep inclination angle Φ, the solar cell module increases in thickness, causing an increase in the weight of the solar cell module or a problem pertaining to an installation space. Sunlight may not be sufficiently condensed on the solar cell elements 2 depending on the season, power fluctuations increase. Accordingly, it is undesirable for the practical use.

In other words, it has been noticed that, in order to maintain practical reliability for a long period of time, to minimize the use of the solar cell elements 2, and to realize a condensing solar cell module at low cost, as shown in FIG. 3, it is important to irradiate sunlight onto the front surface of the solar cell elements 2 evenly, to substantially equally divide a solar flux incident into the interval between the solar cell elements 2, and to distribute the solar flux on the front and back surfaces of the solar cell elements 2.

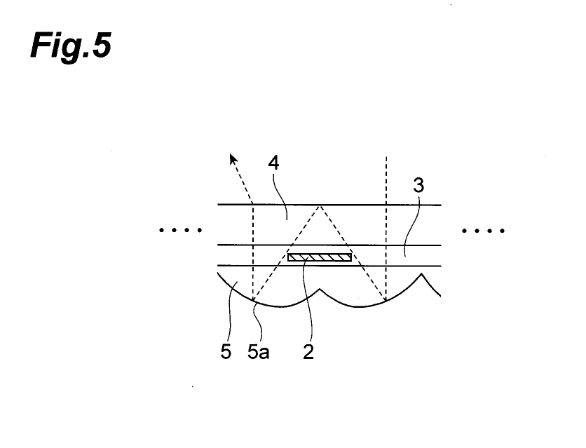

If this condition is satisfied, as shown in FIG. 5, it has been ascertained that there is no case where sunlight is incident again on the light-reflecting surface 5a beyond the solar cell element 2 and leaks outside the solar cell module, and the appearance of the solar cell module glitters and is deteriorated in quality. It has also been ascertained that it is possible to suppress fluctuations in the power generation capacity with seasonal variations or the like, and to provide excellent practicality.

A condition in which the solar flux which is incident into the interval region between the solar cell elements 2 is substantially equally divided, sunlight is condensed on the front surface of the solar cell element 2 evenly, and leak light is suppressed is formularized, as shown in FIG. 3, when one end of the solar cell element 2 is S=0 on the coordinate system, in the following expression, it is necessary that an incident light flux is confined in the solar cell element 2 by the front plate 4 while satisfying the Snell's total reflection condition, and is irradiated at the end position of the solar cell element 2.

$$\begin{matrix}[ Equation 4 ] & \\ \frac{P}{4} + \frac{3 P}{4 a} & \end{matrix}$$

If this is expressed by an expression, the following expression is obtained using a gap t between the light-receiving surface of the solar cell element 2 and the surface of the front plate 4.

$$\begin{matrix}[ Equation 5 ] & \\ \frac{P}{4} + \frac{3 P}{4 a} - tan 2 θ \{ t + \frac{1}{4} tan θ ( P - \frac{P}{a} ) \} - t \cdot tan 2 θ = 0 & \end{matrix}$$

This expression is transformed as follows.

$$\begin{matrix}[ Equation 6 ] & \\ \frac{P}{4} + \frac{3 P}{4 a} - tan 2 θ \{ 2 t + \frac{1}{4} tan θ ( P - \frac{P}{a} ) \} = 0 & ( A )\end{matrix}$$

The inclination angle Φ of the light-reflecting surface 5a is determined on the basis of the angle θ which is calculated from the following condition using a third-order Taylor expansion relating to θ as a measure of the upper limit of θ.

$$\begin{matrix}[ Equation 7 ] & \\ θ = \frac{1}{2} \cdot \frac{- 8 t a + \sqrt{64 {t}^{2} {a}^{2} + 4 {P}^{2} a + 2 {P}^{2} {a}^{2} - 6 {P}^{2}}}{P ( a - 1 )} & \end{matrix}$$

As the result of various studies, it is preferable that, when the refractive index of the front plate 4 is n, the inclination angle Φ of the light-reflecting surface 5a which is appropriate for minimizing variations in performance due to seasonal variations and deterioration in the appearance due to glitter of the solar cell module while satisfying the total reflection conduction in the front plate 4 is expressed by the following expression.

$$\begin{matrix} [ Equation 8 ] & \\ 0.5 \times {sin}^{- 1} ( \frac{1}{n} ) < Φ < \frac{1}{2} \cdot \frac{- 8 t a + \sqrt{64 {t}^{2} {a}^{2} + 4 {P}^{2} a + 2 {P}^{2} {a}^{2} - 6 {P}^{2}}}{P ( a - 1 )} & \end{matrix}$$

It is very appropriate that the following relationship is established on the basis of the angle θ which is given as the solution of Expression (A).

0.5×sin ⁻¹(1/n)rad<Φ<θ+8°

As described above, according to this embodiment, in the region X between the cell interval center line A and the near-cell line D, the inclination angle Φ of the light-reflecting surface 5a is expressed by the following expression in a radian unit.

$$\begin{matrix} [ Equation 9 ] & \\ 0.5 \times {sin}^{- 1} ( \frac{1}{n} ) < Φ < \frac{1}{2} \cdot \frac{- 8 t a + \sqrt{64 {t}^{2} {a}^{2} + 4 {P}^{2} a + 2 {P}^{2} {a}^{2} - 6 {P}^{2}}}{P ( a - 1 )} & \end{matrix}$$

In the region Y near the cell end line C, the inclination angle Φ of the light-reflecting surface 5a is expressed by Φ<0.5×sin ⁻¹(1/n) in a radian unit. Accordingly, even when a solar beam is incident at a place away from the solar cell element 2 in the solar cell module 1, it is possible to efficiently confine the solar beam in the solar cell module 1. For this reason, even when the use of the solar cell elements 2 decreases by decreasing the width S of the solar cell element 2, it is possible to maintain high power generation efficiency. Therefore, it is possible to provide the solar cell module 1 at low cost.

It is possible to sufficiently suppress a decrease in the power generation capacity due to seasonal variations and to solve a problem in that the power generation capacity is significantly lowered during the winter season the like.

Since leakage of light reflected by the light-reflecting surface 5a outside the solar cell module 1 is suppressed, even when the solar cell module 1 is installed on the roof of a house or the roof of an automobile, it is possible to prevent a glittered appearance of the solar cell module 1 and to realize excellent design.

Even when sunlight during the winter season or the like is incident on the solar cell module 1 at a shallow angle due to seasonal variations, there is no case where condensing efficiency of sunlight is degraded, and sunlight hits against the solar cell elements 2 evenly. Accordingly, there is no local heat generation phenomenon (hot spot phenomenon) of the local solar cell elements 2. For this reason, even when the solar cell module 1 is used over a long period of time in a harsh environment, such as a desert area, there is no trouble in thermal deterioration of seal resin forming the seal resin portion 3 or no trouble in defective bonding of a solder. Therefore, it is possible to provide the solar cell module 1 having excellent practicality and reliability.

The back plate 5 is prevented from increasing in thickness, thereby preventing an increase in the thickness of the solar cell module 1. Therefore, it becomes possible to avoid an increase in the size or weight of the solar cell module 1.

The invention is not limited to the foregoing embodiment. For example, although in the foregoing embodiment, the back plate 5 having the light-reflecting surface 5a is formed of a heat-resistant glass substrate or the like, the structure of the back plate 5 is not particularly limited, and the back plate 5 may be formed of, for example, seal resin 3, such as EVA resin. In this case, a reflection loss in the interface decreases, thereby increasing power generation performance.

The bonded interface of the front plate 4 and the resin seal portion 3 may be subjected to uneven roughening. At this time, it is preferable that, when arithmetic mean roughness in the bonded interface of the front plate 4 and the resin seal portion 3 is Ra, and the average interval of concave-convexes in the bonded interface of the front plate 4 and the resin seal portion 3 is Sm, uneven roughening is carried out such that Ra/Sm is equal to or smaller than 0.8. In this case, it is possible to prevent light reflected by the light-reflecting surface 5a from causing unwanted light scattering in the bonded interface of the front plate 4 and the seal resin portion 3, making it possible to further suppress leakage of light outside the solar cell module 1.

Hereinafter, an example corresponding to the foregoing embodiment will be described.

### EXAMPLE

First, a bifacial solar cell element (cell) in which a p-type silicon wafer is used as a substrate, and has an n/p/p+ junction structure having an n layer and a p layer formed through phosphorus diffusion and boron diffusion is prepared. Bifaciality (a power generation efficiency ratio of both surfaces) of the solar cell element is 0.85, and surface conversion efficiency is 15%. The cell size of the solar cell element is 15 mm×125 mm×thickness 200 μm. The surface of the solar cell element is subjected to antireflection and texturing by an optical thin film. That is, the solar cell element has a structure in which a loss in power generation capacity due to a surface reflection loss decreases.

A copper interconnect subject to nickel plating having a width of 2 mm is soldered to the solar cell element by a tin-silver-copper-based lead-free solder, thereby producing a three-series cell string. At this time, an interval is provided between the solar cell elements, and the array pitch P of the solar cell element is 30 mm.

Next, a front plate is prepared. As the front plate, a white sheet tempered glass substrate having a refractive index of 1.49 and thickness of 5 mm is used. The front plate is processed to have the external dimension of 150 mm×150 mm.

Next, a back plate is prepared. As the back plate, a heat-resistant glass substrate having a size of 150 mm×150 mm and thickness of 10 mm is used. The heat-resistance glass substrate is cut by end milling using a diamond bite and ground by buffing such that surface roughness Rz is equal to or smaller than 0.5 μm, thereby forming a back plate having an optical element shape. A valley floor portion (thin portion) of the back plate is subjected to R processing of 0.8 mm through milling using a diamond single-crystal R bite. Accordingly, it is possible to prevent degradation in reliability due to infiltration of moisture into the module through a crack in the thin portion of the back plate and deterioration in appearance quality due to glitter.

The surface roughness Rx of the light-reflecting surface forming an optical element shape is very important from the viewpoint of high power generation efficiency, more preferably, is equal to or smaller than 0.4 μm, and still more preferably, is equal to or smaller than 0.3 μm. That is, the light-reflecting surface of the back plate has high smoothness, such that sunlight is diffused and reflected by the light-reflecting surface. For this reason, an optical condition determined by the total reflection condition in the surface of the front plate is not satisfied, such that sunlight is prevented from leaking outside the solar cell module, thereby avoiding a phenomenon that a loss in power generation occurs.

The shape of the back plate is determined as follows so as to increase the condensing property of sunlight, to suppress degradation in performance due to seasonal variations, and to prevent deterioration in design because leaked reflected light is glittered. That is, the cell interval center line A and the cell center line B (see FIG. 1) substantially match with the thin portion of the back plate. In a region from the cell interval center line A to the cell end line C (see FIG. 1), the profile of the inclination angle Φ of the light-reflecting surface is changing as follows.

In a region near the cell interval center line A, when the refractive index of the front plate is n, the following relationship is established.

Φ>0.5×sin ⁻¹(1/n)=21°

Preferably, the relationship is established.

0.5×sin ⁻¹(1/n)<Φ<θ

As described above, when a condensing magnification relative to the array direction of the solar cell elements is a, and a gap from the solar cell element to the surface of the front plate is t, θ is expressed by the following relational expression.

$$\begin{matrix}[ Equation 10 ] & \\ θ = \frac{1}{2} \cdot \frac{- 8 t a + \sqrt{64 {t}^{2} {a}^{2} + 4 {P}^{2} a + 2 {P}^{2} {a}^{2} - 6 {P}^{2}}}{P ( a - 1 )} & \end{matrix}$$

In order to suppress loss light which is multi-reflected by the light-reflecting surface and leaks outside the solar cell module, and to minimize degradation in power generation performance due to seasonal variations, it is preferable that the above condition is satisfied.

Specifically, since the condensing magnification a is 2, and the gap t between the solar cell element and the front plate is 5.5 mm, 0=40°. Accordingly, in the region near the cell interval center line A, the inclination angle Φ of the light-reflecting surface is determined to be at least Φ>21°, and preferably, 21°<Φ<40°.

In particular, in order to increase reliability, to suppress irregularity of sunlight condensed on the solar cell elements to secure long-term durability performance, and to obtain a respectable appearance when applied to the roof of a house, the roof of an automobile, or the like, the inclination angle Φ of the light-reflecting surface is determined as follows.

0.5×sin ⁻¹(1/n)rad<Φ<θ+8°

The angle θ is given by the following expression.

$$\begin{matrix}[ Equation 11 ] & \\ \frac{P}{4} + \frac{3 P}{4 a} - tan 2 θ \{ 2 t + \frac{1}{4} tan θ ( P - \frac{P}{a} ) \} = 0 & \end{matrix}$$

Specifically, in this example, θ=28°, particularly preferably, 21°<Φ<36°, more preferably, 25°<Φ<34°, and still more preferably, 27°<Φ<32°.

In a region from the cell interval center line A to the cell end line C, while the inclination angle Φ of the light-reflecting surface on the side near the cell interval center line A is in the above range, the closer to the cell end line C, the smaller the inclination angle Φ of the light-reflecting surface. In a region near the cell end line C, the inclination angle Φ of the light-reflecting surface is as follows.

Φ<0.5×sin ⁻¹(1/n)=21°

As described above, in the region from the cell interval center line A to the cell end line C, if a change point is provided beyond Φ=0.5×sin ⁻¹(1/n), it becomes possible to confine solar beams incident from all directions in the solar cell module, and even when the installation direction of the solar cell module is not, for example, due south, to make sunlight efficiently converge to the cells.

Next, a seal resin film sealing the cells is laminated on the cells to form a module. As the seal resin film sealing the cells, two ethylene-vinyl acetate copolymer resin films (EVA film: manufactured by Mitsui Chemicals Fabro, Inc.) having a thickness of 600 μm are prepared. The front plate, the seal resin films, the cell strings, and the back plate are laid up, and vacuum lamination is performed by a usual diaphragm-type vacuum laminator under a hot pressing condition of 140° C. and 17 minutes. Aluminum evaporation is performed on the back plate by a vacuum evaporation method, thereby manufacturing a condensing solar cell module.

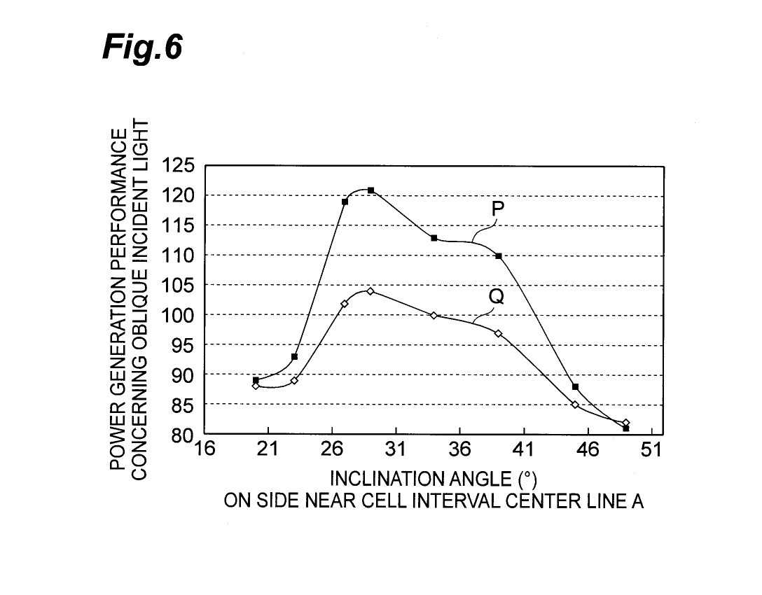

The thus-obtained solar cell module is arranged to be inclined at 60°, and power generation performance is evaluated by a solar simulator under an irradiation condition having simulated the morning and evening during the winter season. As a result of evaluation, as shown in FIG. 6, an improvement of 13% is produced compared to a case where the light-reflecting surface of the back plate does not undergo a gradual decrease in the inclination angle Φ. In FIG. 6, a characteristic P shows a case where there is a change point of Φ=0.5×sin ⁻¹(1/n), and a characteristic Q shows a case where there is no change point of Φ=0.5×sin ⁻¹(1/n) and the inclination angle Φ is constant. Here, the power generation performance ratio when the inclination angle Φ of the light-reflecting surface is constant to 34° is 100% (reference value).

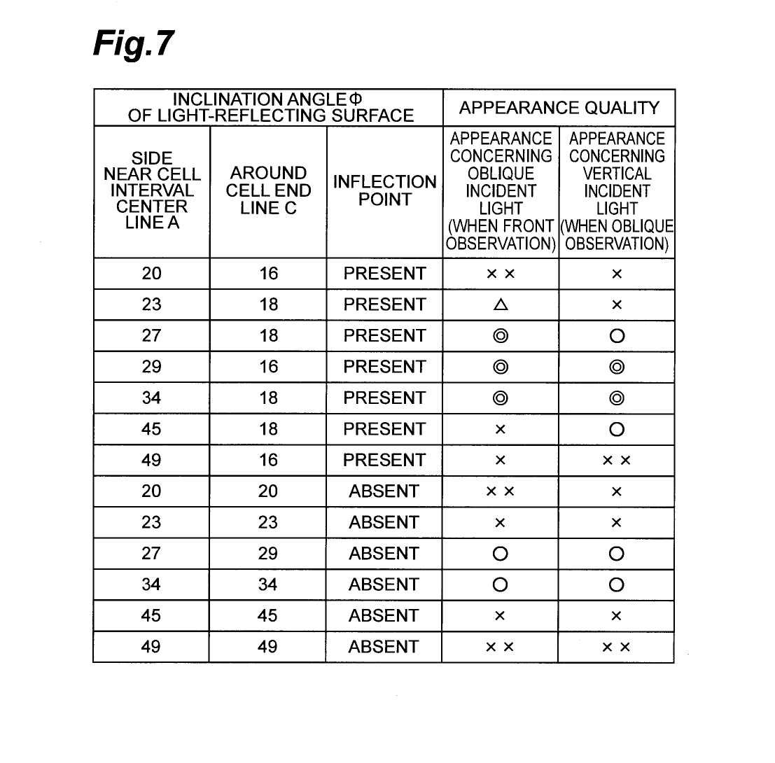

If the inclination angle Φ of the light-reflecting surface has a change point of Φ=0.5×sin ⁻¹(1/n), as shown in FIG. 7, when sunlight is incident at a shallow angle, such as morning and evening, a problem in that the solar cell module glitters and has an unsatisfactory appearance is solved. Accordingly, even when the solar cell module is installed in a house having an inclined roof, it is possible to obtain a solar cell module having excellent design without any problems. Even when the installation direction of the solar cell module is east, west, or the like, not due south, a decrease in efficiency is suppressed to be within 20% compared to due south, thereby obtaining a solar cell module having excellent practicality.

### Comparative Example

Relative to the back plate described in the foregoing example, a back plate was formed in a shape such that the inclination angle Φ of the light-reflecting surface in the region from the cell interval center line A to the cell end line C is constant to 20°<0.5×sin ⁻¹(1/n), and a region where the relationship Φ>0.5×sin ⁻¹(1/n) is satisfied is not provided on the side near the cell interval center line A.

In this case, when compared to the foregoing example, the power generation ability was lowered by 30% at the installation angle having simulated the winter season. It was ascertained that, under a condition that straight light is irradiated on the solar cell module substantially from the front, efficiency was lowered by 47% or more. Accordingly, it can be said that the back plate leaks most of sunlight, does not contribute to condensing on the cells, and is lacking in practicality.

### INDUSTRIAL APPLICABILITY

The invention provides a solar cell module capable of suppressing light leakage from the front plate and improving an optical confinement property.

1.-4. (canceled)

5. A solar cell module comprising:
a plurality of solar cell elements;
a front plate which is arranged on the front side of the solar cell elements; and
a back plate which is arranged on the back side of the solar cell elements and has a light-reflecting surface reflecting sunlight incident from the front plate toward the front plate,
wherein the solar cell elements are of a bifacial type which is configured to generate power on both surfaces,
the light-reflecting surface is inclined relative to the array direction of the solar cell elements to be concave with a cross point of a cell interval center line passing through the center of an interval region of adjacent solar cell elements and the light-reflecting surface as an extreme point, and the thickness of the back plate at a place corresponding to the cell interval center line is smaller than the thickness of the back plate at a place corresponding to a cell center line passing through each solar cell element, and
when the refractive index of the front plate is n, the inclination angle Φ of the light-reflecting surface in a concave extreme point-side portion of a region of the light-reflecting surface corresponding to the interval region is greater than 0.5×sin ⁻¹(1/n) rad.

6. The solar cell module according to claim 5,
wherein, at a position of the light-reflecting surface corresponding to near the edge of each solar cell element, there is a point where the inclination angle Φ of the light-reflecting surface becomes 0.5×sin ⁻¹(1/n) rad.

7. The solar cell module according to claim 5,
wherein the inclination angle al of the light-reflecting surface in a portion on the solar cell element side of a region of the light-reflecting surface corresponding to the interval region is smaller than 0.5×sin ⁻¹(1/n) rad.

8. The solar cell module according to claim 5,
wherein, when the array pitch of the solar cell elements is P, a condensing magnification relative to the array direction of the solar cell elements is a, and the distance between the solar cell element to the surface of the front plate is t, the inclination angle Φ of the light-reflecting surface in a concave extreme point-side portion of the light-reflecting surface is expressed by the following expression:
$$\begin{matrix} [ Equation 12 ] & \\ 0.5 \times {sin}^{- 1} ( \frac{1}{n} ) rad < Φ < \frac{1}{2} \cdot \frac{- 8 t a + \sqrt{64 {t}^{2} {a}^{2} + 4 {P}^{2} a + 2 {P}^{2} {a}^{2} - 6 {P}^{2}}}{P ( a - 1 )} rad & \end{matrix}$$
